(19) United States
(12) Patent Application Publication
(10) Pub. No.: US 2004/0248047 A1
(43) Pub. Date: Dec. 9, 2004

(54) Method of forming thin-film pattern

(75) Inventor: Hideki Kato, Iwata-gun (JP)

Correspondence Address: OLIFF & BERRIDGE, PLC, P.O. BOX 19928, ALEXANDRIA, VA, 22320, US

(73) Assignee: MINEBEA CO., LTD., Kitasaku-gun (JP)

(21) Appl. No.: 10/848,120

(22) Filed: May 19, 2004

(30) Foreign Application Priority Data
Jun. 9, 2003 (JP) 2003-164173

(51) Int. Cl. G03F 7/00

(52) U.S. Cl. 430/313; 430/315; 430/330

(57) ABSTRACT

A thin-film pattern is formed by a method comprising the steps of: (a) applying general purpose novolak based photoresist on a substrate thereby forming a photoresist film; (b) patterning the photoresist film; (c) forming a dielectric multi-layer film (Ta₂O₅/SiO₂) by a PND method so as to entirely cover the substrate including portions occupied by the patterned photoresist film, while the substrate is heated up to 200 to 350 degrees C.; and (d) immersing the substrate in a compound liquid which is made up such that oxidizing agent (hydrogen peroxide, or nitric acid) is mixed with sulfuric acid with a mixing ratio of the oxidizing agent to the sulfuric acid set preferably at 1/5 or less in terms of volume, whereby the photoresist film is dissolved and the dielectric multi-layer formed on the photoresist film is lifted off from the substrate.

### BACKGROUND OF THE INVENTION

1. Field of the Invention

The present invention relates to a method of forming a thin-film pattern by using a lift-off method.

2. Description of the Related Art

A lift-off method for producing a thin-film pattern is generally performed such that a photoresist film configured in a desired pattern is formed on a substrate, then a thin film is formed by a physical vapor deposition (PVD) method so as to entirely cover the substrate including portions occupied by the photoresist film patterned, and that the photoresist film is dissolved by a resist remover thereby lifting off the thin film formed on the photoresist film. Thus, a thin film is formed with a predetermined pattern.

In order to gain a dielectric multi-layer film for use as a wavelength filter having a good weatherability and at the same time excellent optical characteristics, a substrate must be heated up to 150 to 350 degrees C. at the process of forming a film, and also assistance of ions may be applied as required. However, if a film is formed under such conditions, the photoresist film formed on the substrate is denatured, and therefore may not be totally removed (problem of resist remains) by a resist remover thus prohibiting fabrication of a precise thin-film pattern. Under the circumstances, in order to inhibit generation of the problem of resist remains, methods using metal or polyimide based photoresist as a lift-off material have been developed and put into practice.

One of methods using metal as a lift-off material is disclosed in, for example, Japanese Patent Application Laid-Open No. H05-55749. The method is explained in FIGS. 5A to 5G, wherein a metal film (Ni/Cu) 2 is formed on a substrate 1 (FIG. 5A); a photoresist film 3 is formed on the metal film 2 (FIG. 5B); the photoresist film 3 is processed into a predetermined pattern (FIG. 5C); the metal film 2 is etched away according to the patterned photoresist film 3 acting as a masking jig thereby exposing the substrate 1 in accordance with the pattern of the photoresist film 3 (FIG. 5D); the photoresist film 3 remaining on the metal film 2 is dissolved to be removed (FIG. 5E); a dielectric multi-layer film 4 is formed so as to entirely cover the substrate 1 including portions occupied by the metal film 2 remaining (FIG. 5F); and the metal film 2 is etched away so as to lift off portions of the dielectric multi-layer film 4 formed thereon from the substrate 1 whereby remaining portions of the dielectric multi-layer film 4, which constitute the predetermined pattern, are left on the substrate 1 (FIG. G).

Another method using metal as a lift-off material is explained in FIGS. 6A to 6F (in FIGS. 6A to 6F, like reference numerals refer to like films in FIGS. 5A to 5G), wherein a photoresist film 3 is formed on a substrate 1 (FIG. 6A); the photoresist film 3 is processed into a predetermined pattern (FIG. 6B); a metal film 2 is formed so as to entirely cover the substrate 1 including portions occupied by the photoresist film 3 patterned (FIG. 6C); the patterned photoresist film 3 is dissolved thereby lifting off portions of the metal film 2 formed thereon from the substrate 1 thus exposing the substrate 1 in accordance with the pattern of the photoresist film 3 (FIG. 6D); a dielectric multi-layer film 4 is formed so as to entirely cover the substrate 1 including portions occupied by the metal film 2 (FIG. 6E); and the metal film 2 is etched away lifting off portions of the dielectric multi-layer film 4 formed thereon from the substrate 1 whereby remaining portions of the dielectric multi-layer film 4, which constitute the predetermined pattern, are left on the substrate 1 (FIG. 6F).

On the other hand, one of methods using polyimide based photoresist as a lift-off material is disclosed in, for example, Japanese Patent Application Laid-Open No. H07-227687 (refer to FIG. 3 therein), where a polyimide based photoresist film is formed on a substrate, then a general lift-off method is performed such that the photoresist film formed is patterned, a dielectric multi-layer film is formed entirely on the substrate, and portions of the photoresist film remaining so as to constitute a pattern are dissolved for lifting off portions of the dielectric multi-layer film formed thereon. In the lift-off process, an alkaline solution, such as compound liquid formed of hydrazine hydrate and ethylenediamine is used as a resist remover (refer to paragraph [0058] thereof). In this connection, an inorganic system remover comprising sulfuric acid mixed with oxidizing agent (hydrogen peroxide, nitric acid, and the like) is often used as a resist remover for a positive photoresist, such as general purpose novolak based photoresist, because of its excellent removing ability (refer to Japanese Patent Application Laid-Open No. 2002-76272).

In the aforementioned methods using metal as a lift-off material, a process of forming a metal film and a process of etching the metal film formed are additionally required, which makes the methods cumbersome and complicated, and also which requires additional equipments for the processes, thus inviting cost increase. Also, in the method using polyimide based photoresist as a lift-off material, there is a possibility that an alkaline solution used as a resist remover has an adverse effect on a substrate and a thin film (a dielectric multi-layer film) formed on the substrate when the substrate is immersed in the alkaline solution for a long time.

When a substrate must be heated at the time of forming a film, the problem of resist remains cannot be prevented from taking place by just simply using the aforementioned inorganic system remover comprising sulfuric acid mixed with oxidizing agent. Consequently, use of such an inorganic system remover must be abandoned at the process of patterning a dielectric multi-layer film in a lift-off method.

### SUMMARY OF THE INVENTION

In view of the problems described above, the present inventor has studied various combinations of general purpose novolak based photoresist and the inorganic system remover described above and found out that photoresist is better removed when oxidizing agent is added in an amount smaller than a normal addition amount in a lift-off method. This is due to a fact that dissolution of photoresist starts from its sides in a lift-off method, and it is assumed that compound liquid of sulfuric acid and oxidizing agent has its viscosity lowered by reducing an amount of oxidizing agent added to sulfuric acid and therefore easily reaches photoresist located under a thin film in a reduced time.

The present invention has been made on the basis of the above findings, and it is an object of the present invention to provide a method of forming a thin-film pattern, in which generation of resist remains is surely prevented without changing the basic processes of a general lift-off method whereby productivity can be enhanced and production cost can be reduced.

In order to achieve the object, according to one aspect of the present invention, a method of forming a thin-film pattern comprises: a first process of forming a photoresist film with a predetermined pattern on a substrate; a second process of forming a thin film so as to entirely cover the substrate including portions occupied by the patterned photoresist film while the substrate is heated; and a third process of dissolving the photoresist film by means of compound liquid of sulfuric acid and oxidizing agent thereby removing the thin film located on the photoresist film from the substrate. In the method described above, the compound liquid, in which a mixing ratio of oxidizing agent to sulfuric acid is substantially reduced, even to zero in some instances, can be used, whereby the problem of resist remains can be eliminated at the third process, and a thin-film pattern can be formed by a usual lift-off method even when the substrate must be heated up. In this connection the mixing ratio of oxidizing agent to sulfuric acid is 2/5 or smaller in terms of volume. Here, the oxidizing agent may be of any kinds, such as hydrogen peroxide, nitric acid, ammonium persulfide, and chromic acid, but hydrogen peroxide and nitric acid are preferred due to their strong oxidizing power.

In the one aspect of the present invention, the compound liquid may be heated up to a temperature ranging from 50 to 70 degrees C. when the third process is performed, because a temperature exceeding 70 degrees makes it happen that oxidizing agent, especially hydrogen peroxide, is broken down easily.

In the one aspect of the present invention, an ultrasonic wave may be applied to the compound liquid when the third process is performed, so that the photoresist can be removed effectively.

In the one aspect of the present invention, the photoresist film formed at the first process may be a two-layer film which is composed of two kinds of photoresists different in heat resistance from each other, and which is be structured such that an upper layer thereof is constituted by one photoresist of the two kinds having a heat resistance that is higher than a heat resistance of the other one of the two kinds, and that is high enough to withstand a temperature to which the compound liquid is heated up. With this structure, the photoresist film stably maintains its overhand configuration when the substrate is heated up for the film formation.

In the one aspect of the present invention, the photoresist film formed and patterned at the first process may be subjected to exposure before the second process, so that the reaction between the photoresist and the resist remover is facilitated thereby speeding up dissolution of the photoresist at the third process.

In the one aspect of the present invention, the thin film formed at the second process may be a dielectric multi-layer film. While any kinds of thin films can be formed by the method of the present invention, the method is useful especially in forming a dielectric multi-layer, at which time the substrate must be heated up to a comparatively high temperature.

In the one aspect of the present invention, the dielectric multi-layer film may be constructed such that Ta₂O₅ and SiO₂ films are alternately layered.

Consequently, according to the method of forming a thin-film pattern of the present invention, the problem of resist remains can be surely eliminated without changing the basic process of a usual lift-off method even when a substrate must be heated up at the process of forming a film, whereby productivity can be greatly enhanced and production cost can be significantly reduce.

### BRIEF DESCRIPTION OF THE DRAWINGS

FIGS. 1A to 1D constitute an explanatory process chart of a method for forming a thin-film pattern according to a first embodiment of the present invention;

FIGS. 2A to 2E constitute an explanatory process chart of a method for forming a thin-film pattern according to a second embodiment of the present invention;

FIG. 3 is a graph of optical characteristics on sample pieces of one Example;

FIG. 4 is a graph of optical characteristics on sample pieces of another Example;

FIGS. 5A and 5G constitute an explanatory process chart of one conventional method for forming a thin-film pattern by using metal as a lift-off material; and

FIGS. 6A to 6F constitute an explanatory process chart of another conventional method for forming a thin-film pattern by using metal as a lift-off material.

### DETAILED DESCRIPTION OF THE PREFERRED EMBODIMENTS

Preferred embodiments of the present invention will hereinafter be described with reference to the accompanying drawings.

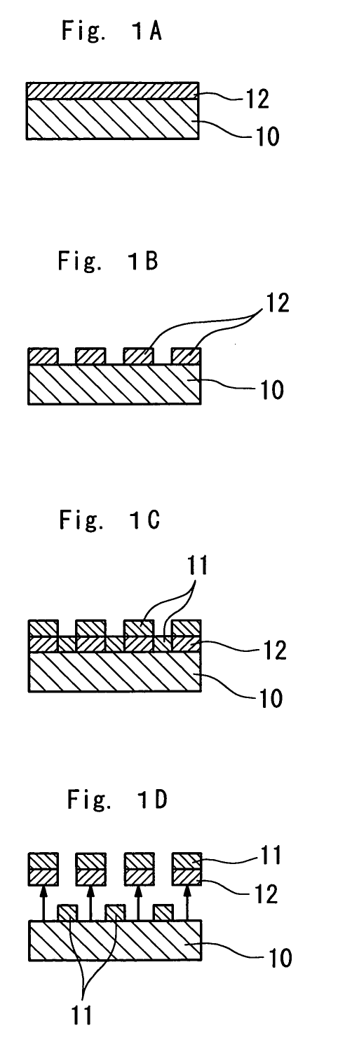

In a method of forming a thin-film pattern according to a first embodiment of the present invention explained in FIGS. 1A to 1D, a dielectric multi-layer film (thin film) is formed on a substrate (glass in the embodiment) so as to finally constitute a predetermined pattern. The method is performed such that general purpose novolak based photoresist is applied to a substrate 10 by, for example, a spin coat method thereby forming a photoresist film 12 (FIG. 1A); the photoresist film 12 is patterned by exposure and development (FIG. 1B); a dielectric multi-layer film 11 with a thickness of 2 to 3 μm is formed by a PVD method, such as a vacuum deposition method, a sputtering method, an ion plating method, or the like while the substrate is heated up to 200 to 350 degrees C., so as to entirely cover the substrate 10 including portions occupied by the photoresist film 12 patterned (FIG. 1C); and the substrate 10 is immersed in a after-mentioned resist remover heated up to 50 to 70 degrees C. so that the photoresist film 12 located under the dielectric multi-layer film 11 is dissolved thereby lifting off the dielectric multi-layer film 11 from the substrate 10 (FIG. 1D). In the method, the dielectric multi-layer film 11 is formed of Ta₂O₅ and SiO₂ films layered alternately in a vacuum chamber by taking in O₂.

The aforementioned resist remover to dissolve and remove the photoresist film 12 is compound liquid of sulfuric acid (96%) mixed with hydrogen peroxide (34.5%), or compound liquid of sulfuric acid (96%) mixed with nitric acid (60%). In case of the compound of sulfuric acid mixed with hydrogen peroxide, a mixing ratio of hydrogen peroxide to sulfuric acid is set at 2/5 or less, preferably 0.5/5 to 0.005/5 in terms of volume, and in case of the compound liquid of sulfuric acid mixed with nitric acid, a mixing ratio of nitric acid to sulfuric acid is set at 2/5 or less, preferably 1/5 to 0.1/5 in terms of volume.

In the method of forming a thin-film pattern as described above, since compound liquid of sulfuric acid mixed with oxidizing agent (hydrogen peroxide, or nitric acid) as a resist remover is made up such that the amount of oxidizing agent added to sulfuric acid is significantly reduced, the viscosity of the compound liquid is lowered, whereby the compound liquid easily reaches and penetrates into the photoresist film 12 located under the dielectric multi-layer film 11 at the lift-off process shown in FIG. 1D. As a result, the photoresist film 12 is surely removed from the substrate 10, thus producing a precise thin-film pattern. Further, the series of processes in the method of the present invention, which are not practically different from the processes in a general lift-off method, are not so much complicated compared with the method using metal as a lift-off material, and also the method of the present invention is free from worry about any adverse effects on quality (denaturation) which is caused due to a long time immersion in an alkaline solution in the method using polyimide based photoresist as a lift-off material.

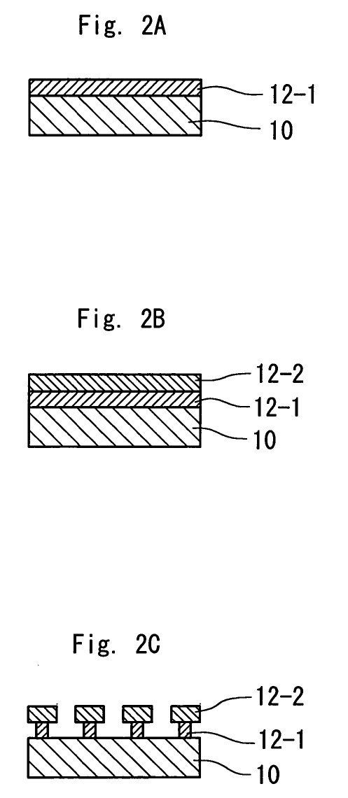

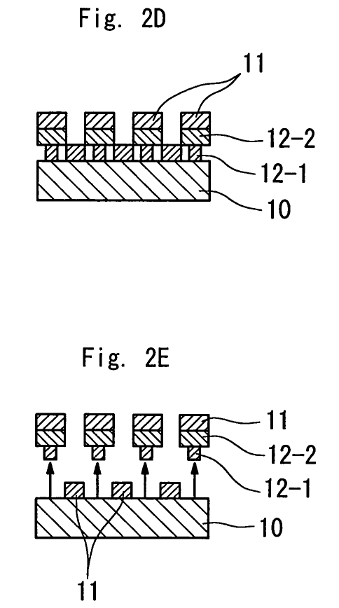

A method of forming a thin-film pattern according to a second embodiment of the present invention will now be described with reference to FIGS. 2A to 2E. The method according to the second embodiment features application of two kinds of photoresists having respective heat resistances different from each other. The method is performed such that a first photoresist having a normal heat resistance is applied onto a substrate (glass in the embodiment) 10 thereby forming a first photoresist film 12-1 (FIG. 2A); a second photoresist having a heat resistance, that is higher than the heat resistance of the first photoresist, and that is high enough to withstand a temperature to which the substrate 10 is to be heated up, is applied onto the first photoresist film 12-1 thereby forming a second photoresist film 12-2 (FIG. 2B); then like in the method according to the first embodiment, the first and second photoresist films 12-1 and 12-2 are patterned by exposure and development (FIG. 2C); a dielectric multi-layer film 11 with a thickness of 2 to 3 μm is formed by a PVD method, such as a vacuum deposition method, a sputtering method, an ion plating method, or the like while the substrate is heated up to 200 to 350 degrees C., so as to entirely cover the substrate 10 including portions occupied by the first and second photoresist films 12-1 and 12-2 patterned (FIG. 2D); and the substrate 10 is immersed in a resist remover (compound liquid of sulfuric acid and oxidizing agent as described above) heated up to 50 to 70 degrees C. so that the first and second photoresist films 12-1 and 12-2 located under the dielectric multi-layer film 11 are dissolved thereby lifting off the dielectric multi-layer film 11 from the substrate 10 (FIG. 2E).

The first and second photoresist films 12-1 and 12-2, when their exposure characteristics are appropriately changed, can be easily patterned such that the second photoresist film 12-2 has overhang from the first photoresist film 12-1 as shown in FIG. 2C. Also, since the two-layer photoresist film is structured such that its upper layer is constituted by the second photoresist film 12-2 which has a heat resistance high enough to withstand a temperature to which the substrate 10 is to be heated up, and which therefore is prevented from having its edges deformed if the substrate 10 is heated at the film forming process shown in FIG. 2D, the pattern once formed can be stably maintained, consequently realizing a precise thin-film pattern.

In the methods according to the first and second embodiments of the present invention, the photoresist films 12, and 12-1 and 12-2, which are patterned (FIGS. 1B and 2C, respectively), may be subjected to exposure again. This facilitates the reaction between the photoresist and the resist remover at the process of lift-off (FIGS. 1D and 2E, respectively) thereby speeding up the dissolution of the photoresist. That is to say, the time for lift-off is shortened thus enhancing productivity.

### EXAMPLES

### Example 1

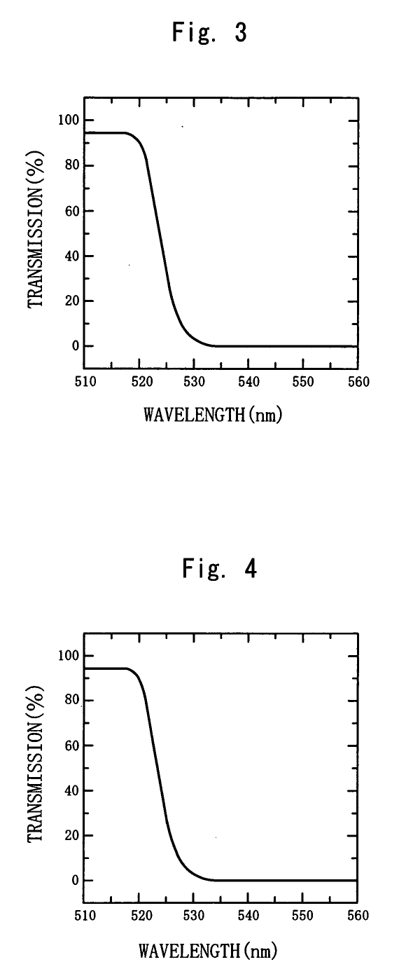

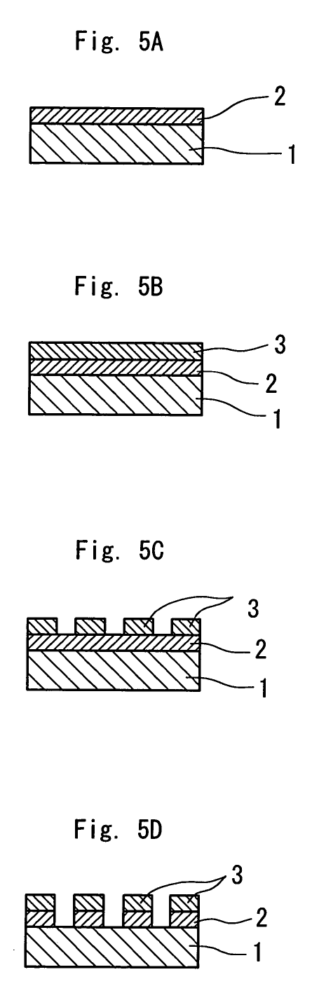

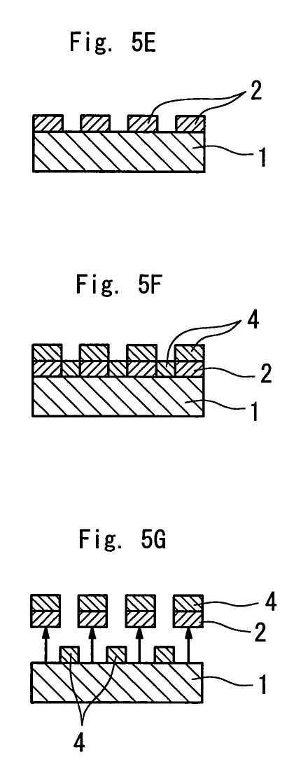

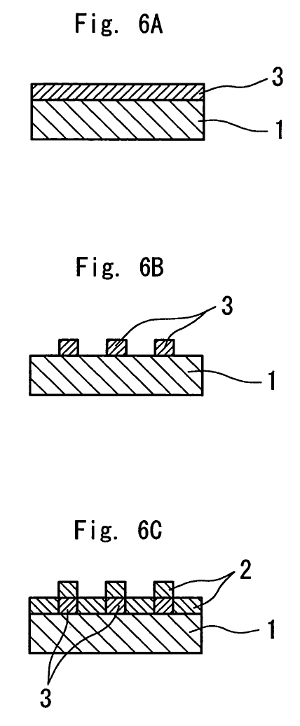

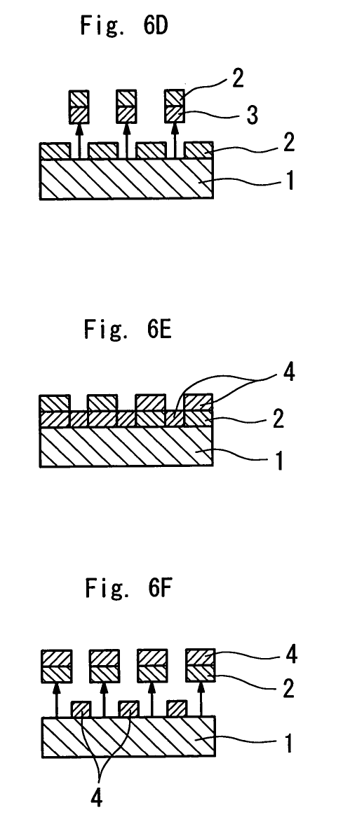

Sample pieces were each produced such that a dielectric multi-layer film of Ta₂O₅ and SiO₂ with a thickness of 3 μm was formed on a glass substrate by a PVD method while the substrate was heated up to 250 degrees C. Compound liquid for a resist remover, which was made up such that sulfuric acid (96%) and hydrogen peroxide (34.5%) were mixed in a mixing ratio of 50:1 in terms of volume, was put in a bath and heated up to 60 degrees C., and the sample pieces produced as described above were immersed in the compound liquid for 1 minute, 30 minutes, 60 minutes, 3 hours, and 6 hours, respectively, thereby achieving several different sample pieces. The sample pieces were subjected to a reliability test to gain transmission characteristic. In this connection, some sample pieces that were not immersed in the resist remover were subjected to the same reliability test for comparison purpose. The test result is shown in FIG. 3.

As known from the result shown in FIG. 3, all of the sample pieces immersed in the resist remover for different time lengths have transmission curves virtually coincident with the transmission curves of the sample pieces not immersed in the resist remover. Thus, it is verified that the resist remover formed of the compound liquid containing sulfuric acid and hydrogen peroxide in a predetermined mixing ratio does not give ant damages to the dielectric multi-layer film.

### Example 2

In Example 2, sample pieces were produced in the same way as in Example 1 except that a resist remover was constituted by compound liquid made up such that sulfuric acid (96%) and nitric acid (60%) were mixed in a mixing ratio of 50:6 in terms of volume. The sample pieces thus produced including those not immersed in the resistor remover were subjected to the same reliability test as in Example 1, and the test result is shown in FIG. 4.

As known from the result shown in FIG. 4, all of the sample pieces immersed in the resist remover have transmission curves virtually coincident with the transmission curves of the sample pieces not immersed in the resist remover. Thus, it is verified that the resist remover formed of the compound liquid containing sulfuric acid and nitric acid in a predetermined mixing ratio do not give ant damages to the dielectric multi-layer film.

### Example 3

In Example 3, two types of sample pieces were prepared. First sample pieces were each prepared such that novolak based photoresist was applied onto a glass substrate thereby forming a photoresist film with a thickness of 4 to 5 μm and that the photoresist film was subjected to exposure and development for patterning, and second sample pieces were each prepared by subjecting the photoresist film on the first sample piece to another exposure process (exposure condition was the same as for the first exposure). The aforementioned first and second sample pieces in process were heated up to 300 degrees C., and a dielectric multi-layer film was formed on the photoresist film patterned. Then, the first and second sample pieces in process were immersed in compound liquid as a resist remover, which was made up such that sulfuric acid (96%) and nitric acid (60%) were mixed in a mixing ratio of 50:6 in terms of volume, and which was put in a bath and heated up to 60 degrees C., and times required for the photoresist films to be completely lifted off were measured. It took about 1.5 hours for the photoresist films on the first sample pieces to be completely dissolved, and about 0.7 hours on the second sample pieces. As known from this result, subjecting a photoresist film to another exposure is very effective in speeding up dissolution of photoresist.

While the present invention has been illustrated and explained with respect to specific embodiments thereof, it is to be understood that the present invention is by no means limited thereto but encompasses all changes and modifications that will become possible within the scope of the appended claims.

1. A method of forming a thin-film pattern, the method comprising:
a first process of forming a photoresist film with a predetermined pattern on a substrate;
a second process of forming a thin film so as to entirely cover the substrate including portions occupied by the patterned photoresist film while the substrate is heated; and
a third process of dissolving the photoresist film by means of compound liquid composed of sulfuric acid mixed with oxidizing agent thereby removing the thin film located on the photoresist film from the substrate.

2. A method of forming a thin-film pattern according to claim 1, wherein the compound liquid is made up such that a mixing ratio of the oxidizing agent to the sulfuric acid is 2/5 or smaller in terms of volume.

3. A method of forming a thin-film pattern according to claim 1, wherein the oxidizing agent is hydrogen peroxide.

4. A method of forming a thin-film pattern according to claim 1, wherein the oxidizing agent is nitric acid.

5. A method of forming a thin-film pattern according to claim 1, wherein the compound liquid is heated up to a temperature of 50 to 70 degrees C. when the third process is performed.

6. A method of forming a thin-film pattern according to claim 1, wherein an ultrasonic wave is applied to the compound liquid when the third process is performed.

7. A method of forming a thin-film pattern according to claim 1, wherein the photoresist film formed at the first process is a two-layer film which is composed of two kinds of photoresists different in heat resistance from each other, and which is structured such that an upper layer thereof is constituted by one photoresist of the two kinds having a heat resistance that is higher than a heat resistance of the other one of the two kinds, and that is high enough to withstand a temperature to which the compound liquid is heated up.

8. A method of forming a thin-film pattern according to claim 1, wherein the photoresist film formed and patterned at the first process is subjected to exposure before the second process.

9. A method of forming a thin-film pattern according to claim 1, wherein the thin film formed at the second process is a dielectric multi-layer film.

10. A method of forming a thin-film pattern according to claim 9, wherein the dielectric multi-layer film is constructed such that Ta₂O₅ and SiO₂ films are alternately layered.
